(19) United States
(12) Patent Application Publication
(10) Pub. No.: US 2025/0234743 A1
(43) Pub. Date: Jul. 17, 2025

(54) DISPLAY DEVICE AND METHOD OF MANUFACTURING THE SAME

(71) Applicant: Samsung Display Co., Ltd., Yongin-si (KR)

(72) Inventors: JAESUNG LIM, Yongin-si (KR); JAE-HOON KIM, Yongin-si (KR); JAEKWON HWANG, Yongin-si (KR)

(21) Appl. No.: 18/825,840

(22) Filed: Sep. 5, 2024

(30) Foreign Application Priority Data
Jan. 12, 2024 (KR) 10-2024-0005290

(51) Int. Cl. H10K 59/38; H10K 59/12; H10K 59/122; H10K 59/70; H10K 59/80; H10K 102/00

(52) U.S. Cl. CPC H10K 59/38; H10K 59/1201; H10K 59/122; H10K 59/70; H10K 59/8722; H10K 2102/331; H10K 2102/351

(57) ABSTRACT

A display device includes a first substrate including a base layer, a pixel definition layer above the base layer, and defining a first opening and a second opening, a first light-emitting layer in the first opening, and including an organic light-emitting material, and a second light-emitting layer in the second opening, and including a first quantum dot, and a second substrate above the first substrate, and including a base substrate, a barrier wall under the base substrate, and defining a first barrier wall opening overlapping the first opening, and a second barrier wall opening overlapping the second opening, a first functional layer in the first barrier wall opening, and including a polymer-based material, a moisture-absorbing layer in the first barrier wall opening for absorbing a moisture emitted from the polymer-based material, and a second functional layer in the second barrier wall opening, and including the polymer-based material.

### CROSS-REFERENCE TO RELATED APPLICATION(S)

The present application claims priority to, and the benefit of, Korean Patent Application No. 10-2024-0005290, filed on Jan. 12, 2024, in the Korean Intellectual Property Office, the entire disclosure of which is incorporated herein by reference.

### BACKGROUND

### 1. Field

The present disclosure relates to a display device including a quantum dot, and a method of manufacturing the display device.

### 2. Description of the Related Art

Various display devices applied to multimedia devices, such as televisions, mobile phones, tablet computers, navigation devices, and game devices, are being developed. The display devices employ a so-called self-emissive display element that displays images by emitting light using a light-emitting material containing an organic compound.

In addition, a light-emitting element that employs a quantum dot as its light-emitting material is being developed to improve a color reproducibility of the display device.

### SUMMARY

The present disclosure provides a display device including a quantum dot and an organic light-emitting material as its light-emitting material, and having improved luminous efficiency and lifespan.

The present disclosure provides a method of manufacturing the display device.

Embodiments of the present disclosure provide a display device including a first substrate including a base layer, a pixel definition layer above the base layer, and defining a first opening and a second opening, a first light-emitting layer in the first opening, and including an organic light-emitting material, and a second light-emitting layer in the second opening, and including a first quantum dot, and a second substrate above the first substrate, and including a base substrate, a barrier wall under the base substrate, and defining a first barrier wall opening overlapping the first opening, and a second barrier wall opening overlapping the second opening, a first functional layer in the first barrier wall opening, and including a polymer-based material, a moisture-absorbing layer in the first barrier wall opening for absorbing a moisture emitted from the polymer-based material, and a second functional layer in the second barrier wall opening, and including the polymer-based material.

The polymer-based material of the first functional layer may include methacrylic acid, polyacrylic acid, or citric acid.

The moisture-absorbing layer may be above, and may directly contact, the first functional layer.

The first functional layer may have a thickness that is less than a thickness of the second functional layer.

A sum of a thickness of the first functional layer and a thickness of the moisture-absorbing layer may be substantially equal to a thickness of the second functional layer.

An upper surface of the moisture-absorbing layer may contact a lower surface of the base substrate.

The moisture-absorbing layer may include a first moisture-absorbing layer, and a second moisture-absorbing layer under the first moisture-absorbing layer with the first functional layer therebetween.

A lower surface of the first moisture-absorbing layer may directly contact an upper surface of the first functional layer, wherein an upper surface of the second moisture-absorbing layer directly contacts a lower surface of the first functional layer.

The first functional layer may be above, and may directly contact, the moisture-absorbing layer.

A distance from a lower surface of the first functional layer to an upper surface of the first light-emitting layer may be greater than a distance from a lower surface of the second functional layer to an upper surface of the second light-emitting layer, wherein the first functional layer is blocked by the moisture-absorbing layer when viewed in a direction from the first light-emitting layer to the first functional layer.

The display device may further include a sealing member along an edge of the first substrate and the second substrate, and defining an inner space with the first substrate and the second substrate.

The base substrate may include a glass material, wherein the first functional layer, the moisture-absorbing layer, and the base substrate have a light-transmitting property.

The pixel definition layer may define a third opening, wherein the first substrate further includes a third light-emitting layer including a second quantum dot in the third opening, wherein the barrier wall defines a third barrier wall opening overlapping the third opening, and wherein the second substrate further includes a third functional layer in the third barrier wall opening, and including a polymer-based material.

The organic light-emitting material may emit a blue light, wherein the first quantum dot emits a green light, and wherein the second quantum dot emits a red light.

Embodiments of the present disclosure provide a method of manufacturing a display device, the method including forming a second substrate by providing a base substrate, forming a barrier wall on the base substrate, etching the barrier wall to form a first barrier wall opening, a second barrier wall opening, and a third barrier wall opening, and forming a moisture-absorbing layer including a moisture-absorbing material in the first barrier wall opening, forming a functional layer including a polymer-based material, in the first barrier wall opening, the second barrier wall opening, and the third barrier wall opening, forming a first substrate, and coupling the first substrate and the second substrate.

The forming of the moisture-absorbing layer may include providing a moisture-absorbing material in a liquid form to the first barrier wall opening, and curing the moisture-absorbing material by irradiating an ultraviolet ray.

The forming of the moisture-absorbing layer may include providing a moisture-absorbing material in a liquid form to the first barrier wall opening, forming a first moisture-absorbing layer by irradiating an ultraviolet ray, and providing the moisture-absorbing material in the liquid form on the first moisture-absorbing layer, and forming a second moisture-absorbing layer by irradiating an ultraviolet ray.

The forming of the functional layer may be performed between the forming of the first moisture-absorbing layer and the forming of the second moisture-absorbing layer.

The forming of the functional layer may be performed by an inkjet process or a photoresist process.

The first substrate may include a base layer, a pixel definition layer above the base layer and defining a first opening, a second opening, and a third opening, a first light-emitting layer in the first opening and including an organic light-emitting material, a second light-emitting layer in the second opening and including a first quantum dot, and a third light-emitting layer in the third opening and including a second quantum dot, wherein the coupling of the first and second substrates includes aligning the first opening, the second opening, and the third opening to respectively overlap the first barrier wall opening, the second barrier wall opening, and the third barrier wall opening.

According to the above, the efficiency and the lifespan of the light-emitting layer of the display device are improved.

### BRIEF DESCRIPTION OF THE DRAWINGS

The above and other aspects of the present disclosure will become readily apparent by reference to the following detailed description when considered in conjunction with the accompanying drawings wherein:

FIG. 1 is a perspective view of a display device according to one or more embodiments of the present disclosure;

FIG. 2 is a cross-sectional view of a display device according to one or more embodiments of the present disclosure;

FIG. 3 is a cross-sectional view of a light-emitting element included in a display device according to one or more embodiments of the present disclosure;

FIG. 4 is a cross-sectional view of a quantum dot included in a display device according to one or more embodiments of the present disclosure;

FIG. 5 is a cross-sectional view of a display device taken along the line I-I′ of FIG. 1;

FIG. 6 is a cross-sectional view of a display device taken along the line I-I′ of FIG. 1;

FIG. 7 is a cross-sectional view of a display device taken along the line I-I′ of FIG. 1;

FIGS. 8A to 8H are cross-sectional views illustrating a method of manufacturing a display device according to one or more embodiments of the present disclosure;

FIGS. 9A and 9B are cross-sectional views illustrating a method of manufacturing a display device according to one or more embodiments of the present disclosure; and

FIGS. 10A to 10C are cross-sectional views illustrating a method of manufacturing a display device according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

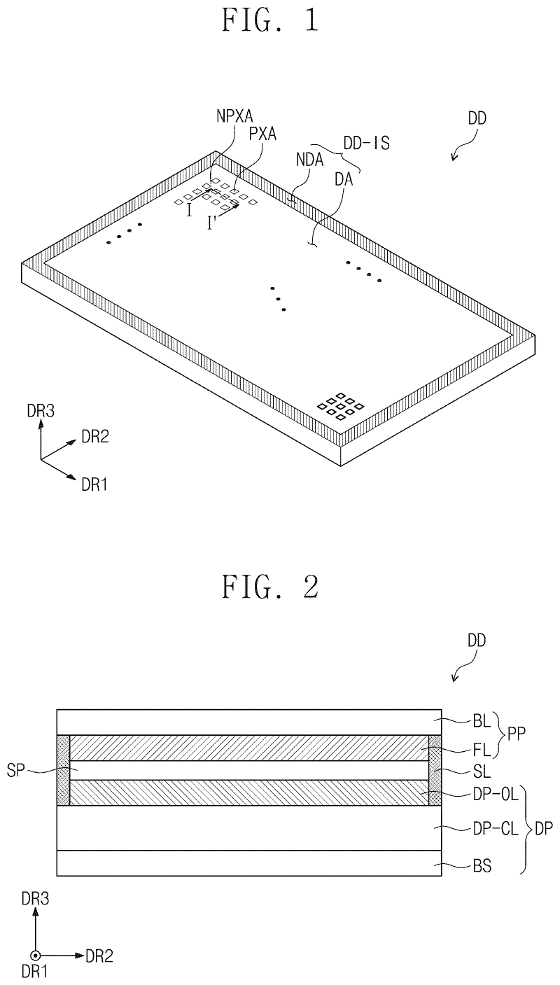

FIG. 1 is a perspective view of a display device DD according to one or more embodiments of the present disclosure, and FIG. 2 is a cross-sectional view of the display device DD according to one or more embodiments of the present disclosure.

FIG. 1 and the following drawings show first, second, and third directional axes DR1, DR2, and DR3, and directions indicated by the first, second, and third directional axes DR1, DR2, and DR3 may be relative to each other, and may be changed to other directions. In addition, the directions indicated by the first, second, and third directional axes DR1, DR2, and DR3 may be referred to as first, second, and third directions, respectively, and may be assigned with the same reference numerals as those of the first, second, and third directional axes DR1, DR2, and DR3. In the present disclosure, the first directional axis DR1 may be substantially perpendicular to the second directional axis DR2, and the third directional axis DR3 may be a normal line direction with respect to the plane defined by the first directional axis DR1 and the second directional axis DR2. In the present disclosure, the term “plane” refers to the plane defined by the first directional axis DR1 and the second directional axis DR2, and the term “cross-section” refers to a plane substantially perpendicular to the plane defined by the first directional axis DR1 and the second directional axis DR2, and substantially parallel to the third directional axis DR3. A thickness direction of the display device DD may indicate a direction substantially parallel to the third direction DR3 that is the normal line direction with respect to the plane defined by the first and second directions DR1 and DR2.

The display device DD may be activated in response to electrical signals. The display device DD may be applied to a large-sized electronic item, such as a television set, a monitor, an outdoor billboard, etc. In addition, the display device DD may be applied to a small and medium-sized electronic item, such as a personal computer, a notebook computer, a personal digital assistant, a car navigation unit, a game unit, a smart phone, a tablet computer, a camera, etc. However, these are merely examples, and the display device DD may be applied to other electronic devices as long as they do not depart from the concept of the present disclosure.

The display device DD may display an image through a display surface DD-IS. The display device DD may include light-emitting areas PXA and a non-light-emitting area NPXA. The display surface DD-IS may be substantially parallel to a plane defined by a first direction DR1 and a second direction DR2. The display surface DD-IS may include a display area DA and a non-display area NDA. The light-emitting areas PXA may be defined in the display area DA. The light-emitting areas PXA may be referred to as pixel areas.

The light-emitting areas PXA may be arranged in a stripe pattern in the display device DD. Referring to FIG. 1, the light-emitting areas PXA may be arranged in a first directional axis DR1 and in a second directional axis DR2. However, the present disclosure should not be limited thereto or thereby, and the light-emitting areas PXA may be arranged in a pentile (PENTILE™) arrangement or in a diamond (Diamond Pixel™) arrangement (PENTILE™ and Diamond Pixel™ being registered trademarks of Samsung Display Co., Ltd., Republic of Korea).

In FIG. 1, the light-emitting areas PXA are shown having similar size, although this is merely an example. According to one or more embodiments, the light-emitting areas PXA may have different sizes depending on a wavelength of light emitted therefrom.

The non-display area NDA may be defined along an edge of the display surface DD-IS. The non-display area NDA may surround the display area DA. However, the present disclosure should not be limited thereto or thereby, the non-display area NDA may be omitted, or the non-display area NDA may be located only at one side of the display area DA.

FIG. 1 shows the display device DD including a flat display surface DD-IS, although it should not be limited thereto or thereby. The display device DD may include a curved display surface or a three-dimensional display surface. The three-dimensional display surface may include a plurality of display areas facing different directions from each other.

In the present disclosure, an upper surface (or a front surface) and a lower surface (or a rear surface) of each member of the display device DD may be defined with respect to the third direction DR3. In more detail, between two surfaces of one member, which face each other with respect to the third direction DR3, one surface that is relatively close to the display surface DD-IS may be defined as the front surface (or the upper surface), and the other surface that is relatively distant from the display surface DD-IS may be defined as the rear surface (or the lower surface). In addition, in the following descriptions, an upper portion (or an upper side) and a lower portion (or a lower side) may be defined with respect to the third direction DR3, the upper portion (or the upper side) may refer to a direction approaching the display surface DD-IS, and the lower portion (or the lower side) may refer to a direction away from the display surface DD-IS.

In the present disclosure, when an element is referred to as being “directly located/directly formed” on another element, there are no intervening elements present therebetween. For example, the term “directly located/directly formed” may mean that two elements contact each other.

Referring to FIG. 2, the display device DD may include a first substrate DP, a second substrate PP located on the first substrate DP, and a sealing member SL located between the first substrate DP and the second substrate PP (as used herein, “located on” may mean “above”).

The first substrate DP may be a display panel DP that substantially generates the image. The first substrate DP of the display device DD may be a light-emitting type display panel. The first substrate DP may include an inorganic light-emitting element including an inorganic light-emitting substance, such as a quantum dot and an organic light-emitting element including an organic light-emitting substance.

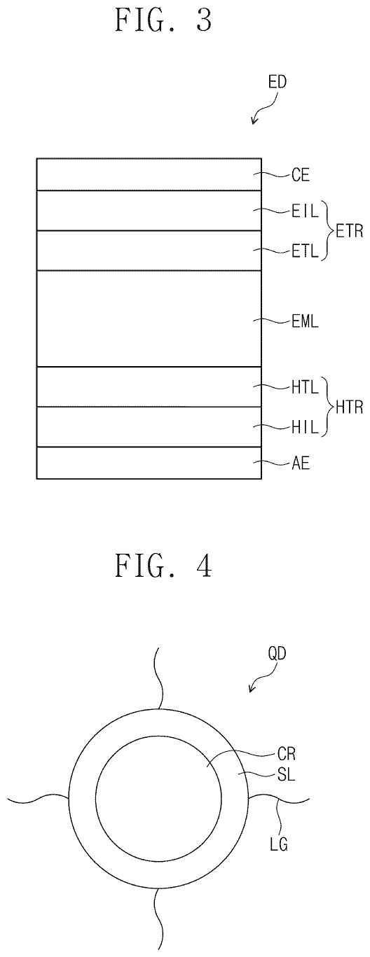

The first substrate DP may include a base layer BS, a circuit element layer DP-CL located on the base layer BS, and a display element layer DP-OL located on the circuit element layer DP-CL. The display element layer DP-OL may include a light-emitting element ED (refer to FIG. 3), and components of the light-emitting element ED will be described later with reference to FIG. 3.

The second substrate PP may be located above the first substrate DP. The second substrate PP may cover the first substrate DP to reduce or prevent foreign substances, moisture, or oxygen from entering the first substrate DP. The second substrate PP may include an optically transparent portion. Accordingly, a light emitted from the first substrate DP may be perceived by a user who is looking at an upper surface of the second substrate PP after passing through the second substrate PP.

The second substrate PP may include a base substrate BL, and an auxiliary layer FL located on a lower portion of the base substrate BL. The base substrate BL may provide a base surface on which the auxiliary layer FL is located. The auxiliary layer FL may provide a functional material to increase a lifespan of the display element layer DP-OL.

The sealing member SL may be located between the first substrate DP and the second substrate PP. The sealing member SL may be located along an edge of each of the first substrate DP and the second substrate PP, and may define an inner space SP together with the first substrate DP and the second substrate PP. The inner space SP may be filled with a nitrogen (N₂) gas.

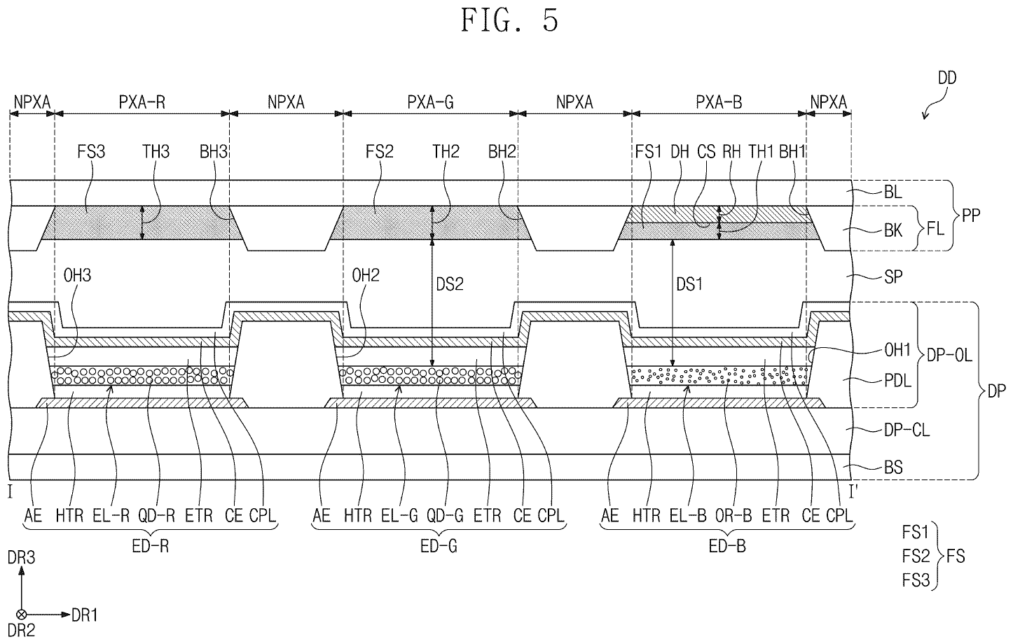

A portion of a material released from the second substrate PP may reach the first substrate DP through the inner space SP. As an example, moisture emitted from a polymer-based material included in first, second, and third functional layers FS1, FS2, and FS3 (refer to FIG. 5) may enter the first substrate DP in a gas or liquid form through the inner space SP. The moisture may react with the light-emitting element ED (refer to FIG. 3) of the display element layer DP-OL and may affect the lifespan of the light-emitting element ED. This will be described in detail with reference to FIGS. 3 and 5.

FIG. 3 is a cross-sectional view of the light-emitting element ED included in the display device DD according to one or more embodiments of the present disclosure.

The light-emitting element ED may include a first electrode AE, a hole transport region HTR, a light-emitting layer EML, an electron transport region ETR, and a second electrode CE. The light-emitting element ED may further include a capping layer CPL (refer to FIG. 5) located on the second electrode CE.

The first electrode AE may have a conductivity. The first electrode AE may be an anode or a cathode. In addition, the first electrode AE may be a pixel electrode, although the present disclosure should not be limited thereto or thereby.

The first electrode AE may be a transmissive electrode, a semi-transmissive electrode, or a reflective electrode. The first electrode AE may include at least one selected from Ag, Mg, Cu, Al, Pt, Pd, Au, Ni, Nd, Ir, Cr, Li, Ca, LiF Mo, Ti, W, In, Sn, or Zn, a combination of two or more compounds selected from the above-mentioned materials, a combination of two or more mixtures selected from the above-mentioned materials, or oxides of the above-mentioned metal materials.

In the case where the first electrode AE is the transmissive electrode, the first electrode AE may include a transparent metal oxide (e.g., indium tin oxide (ITO), indium zinc oxide (IZO), zinc oxide (ZnO), indium tin zinc oxide (ITZO), etc.). In the case where the first electrode AE is the semi-transmissive electrode or the reflective electrode, the first electrode AE may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, a compound thereof, or a mixture thereof (e.g., a mixture of Ag and Mg). According to one or more embodiments, the first electrode AE may have a multi-layer structure of a reflective layer or a semi-transmissive layer, which is formed of the above-mentioned material, and a transparent conductive layer formed of indium tin oxide (ITO), indium zinc oxide (IZO), zinc oxide (ZnO), or indium tin zinc oxide (ITZO). As an example, the first electrode AE may have a three-layer structure of ITO/Ag/ITO, although the present disclosure should not be limited thereto or thereby. As an example, the first electrode AE may include the above-mentioned metal materials, a combination of two or more metal materials selected from the above-mentioned metal materials, or oxides of the above-mentioned metal materials. The first electrode AE may have a thickness of about 700 Å to about 10000 Å. As an example, the thickness of the first electrode AE may be within a range from about 1000 Å to about 3000 Å.

The second electrode CE may be located on the first electrode AE. The second electrode CE may be a cathode or an anode. As an example, when the first electrode AE is the anode, the second electrode CE may be the cathode, and when the first electrode AE is the cathode, the second electrode CE may be the anode. The second electrode CE may be a common electrode. However, the present disclosure should not be limited thereto or thereby.

The second electrode CE may include at least one selected from Ag, Mg, Cu, Al, Pt, Pd, Au, Ni, Nd, Ir, Cr, Li, Ca, LiF Mo, Ti, W, In, Sn, or Zn, a combination of two or more compounds selected from the above-mentioned materials, a combination of two or more mixtures selected from the above-mentioned materials, or oxides of the above-mentioned metal materials.

The second electrode CE may be a transmissive electrode, a semi-transmissive electrode, or a reflective electrode. In the case where the second electrode CE is the transmissive electrode, the second electrode CE may include a transparent metal oxide (e.g., indium tin oxide (ITO), indium zinc oxide (IZO), zinc oxide (ZnO), indium tin zinc oxide (ITZO), etc.).

In the case where the second electrode CE is the semi-transmissive electrode or the reflective electrode, the second electrode CE may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgYb). The second electrode CE may have a multi-layer structure of a reflective layer or a semi-transmissive layer, which is formed of the above-mentioned material, and a transparent conductive layer formed of indium tin oxide (ITO), indium zinc oxide (IZO), zinc oxide (ZnO), or indium tin zinc oxide (ITZO). As an example, each of the lower electrodes may have a three-layer structure of ITO/Ag/ITO. As an example, the second electrode CE may include the above-mentioned metal materials, a combination of two or more metal materials selected from the above-mentioned metal materials, or oxides of the above-mentioned metal materials.

In one or more embodiments, the second electrode CE may be connected to an auxiliary electrode. When the second electrode CE is connected to the auxiliary electrode, a resistance of the second electrode CE may be reduced.

The electron transport region ETR may be located between the light-emitting layer EML and the second electrode CE.

The electron transport region ETR may have a single-layer structure of a single material, a single-layer structure of multiple different materials, or a multi-layer structure of multiple layers including materials different from each other. As an example, the electron transport region ETR may have a single-layer structure of an electron injection layer EIL or an electron transport layer ETL or may have a single-layer structure of an electron injection material and an electron transport material. The electron transport region ETR may have a thickness of about 20 nm to about 150 nm.

The electron transport region ETR may further include zinc oxide. The type of zinc oxide should not be particularly limited, and for example, the electron transport region ETR may include ZnO, ZnMgO, or a combination thereof, and zinc oxide ZnO doped with Li may be included rather than zinc oxide ZnO doped with Mg, however the present disclosure should not be limited thereto or thereby. As an example, the electron injection layer EIL may include zinc oxide, or two or more layers of layers included in the electron transport region ETR may include zinc oxide.

When the electron transport region ETR includes zinc oxide, defects in which an oxygen vacancy occurs on a surface of zinc oxide may be generated. When a trap state occurs by the defects, charges may be trapped and quenched, and thus, luminous efficiency and lifespan of devices may decrease. However, because the light-emitting element ED according to the present disclosure includes a functional layer FS (refer to FIG. 5) containing a polymer-based material, the oxygen vacancy may be reduced or prevented. This will be described in detail later with reference to FIG. 5.

The hole transport region HTR may be located between the first electrode AE and the light-emitting layer EML.

The hole transport region HTR may have a single-layer structure of a single material, a single-layer structure of multiple different materials, or a multi-layer structure of multiple layers including materials different from each other. In one or more embodiments, the hole transport region HTR may have the single-layer structure of multiple different materials, or may have a structure of a hole injection layer HIL/a hole transport layer HTL or a hole injection layer HIL/a hole transport layer HTL/a hole buffer layer, which are sequentially stacked from the first electrode AE. However, the present disclosure should not be limited thereto or thereby.

The hole transport region HTR, the light-emitting layer EML, and the electron transport region ETR of each of the light-emitting elements ED may be located in openings OH1, OH2, and OH3 (refer to FIG. 5) of a pixel definition layer PDL (refer to FIG. 5) and may be separated from a hole transport region HTR, a light-emitting layer EML, and an electron transport region ETR of light-emitting areas adjacent thereto. That is, the hole transport region HTR, the light-emitting layer EML, and the electron transport region ETR may be located in each of the openings OH1, OH2, and OH3.

According to the display device DD, the hole transport region HTR, the light-emitting layer EML, and the electron transport region ETR of each light-emitting element ED may be formed by an inkjet printing method, although the present disclosure should not be limited thereto or there. The hole transport region HTR, the light-emitting layer EML, and the electron transport region ETR may be formed by a method other than the inkjet printing method. In addition, according to one or more embodiments, at least a portion of the hole transport region HTR or at least a portion of the electron transport region ETR may extend to, and may be located on, an upper portion of the pixel definition layer PDL, or may be connected to a portion of the hole transport region HTR or to a portion of the electron transport region ETR located at adjacent light-emitting elements ED.

According to the display device DD, each of the second electrode CE and the capping layer CPL (refer to FIG. 5) may be commonly provided on first, second, and third light-emitting elements ED-B, ED-G, and ED-R, although the present disclosure should not be limited thereto or thereby. According to one or more embodiments, at least one of the second electrode CE and the capping layer may be provided to be separated from each other in neighboring light-emitting areas PXA-B, PXA-G, PXA-R (refer to FIG. 5).

Descriptions on the light-emitting element ED may be applied to the first, second, and third light-emitting elements ED-B, ED-G, and ED-R (refer to FIG. 5). In the display device DD, at least one of the first, second, and third light-emitting elements ED-B, ED-G, and ED-R may be the inorganic light-emitting element where the light-emitting layer includes the inorganic light-emitting substance, and the others of the first, second, and third light-emitting elements ED-B, ED-G, and ED-R may be the organic light-emitting element where the light-emitting layer includes the organic light-emitting substance. As an example, in the display device DD shown in FIG. 5, the first light-emitting element ED-B may be the organic light-emitting element, and the second light-emitting element ED-G and the third light-emitting element ED-R may be the inorganic light-emitting element.

The light-emitting element ED may further include the capping layer CPL (refer to FIG. 5) located on the second electrode CE. The capping layer CPL may have a single-layer or multi-layer structure. The capping layer CPL may be an organic layer or an inorganic layer.

FIG. 4 is a cross-sectional view of a quantum dot QD included in the display device according to one or more embodiments of the present disclosure.

Referring to FIG. 4, the quantum dot QD may include a core CR, and at least one shell SL surrounding the core CR.

The quantum dot QD may include a Group II-VI compound, a Group III-V compound, a Group Ill-VI compound, a Group 1-Ill-VI compound, a Group IV-VI compound, a Group IV element, a Group IV compound, or an arbitrary combination thereof.

The Group II-VI compound may be selected from a binary compound selected from the group consisting of CdSe, CdTe, CdS, ZnS, ZnSe, ZnTe, ZnO, HgS, HgSe, HgTe, MgSe, MgS, or a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, or a mixture thereof, or a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, or a mixture thereof.

The Group III-VI compound may include a binary compound, such as In₂S₃, In₂Se₃, etc., a ternary compound, such as InGaS₃, InGaSe₃, etc., or an arbitrary combination thereof.

The Group I-III-VI compound may be selected from a ternary compound selected from the group consisting of AgInS, AgInS₂, CuInS, CuInS₂, AgGaS₂, CuGaS₂, CuGaO₂, AgGaO₂, AgAlO₂, or a mixture thereof or a quaternary compound selected from the group consisting of AgInGaS₂ or CuInGaS₂.

The Group III-V compound may be selected from a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, GaAlNP, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. The Group III-V compound may further include a Group II metal. For instance, InZnP may be selected as a Group III-II-V compound.

The Group IV-VI compound may be selected from a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

In this case, the binary compound, the ternary compound, or the quaternary compound may exist in the particles at a uniform concentration or may exist in the same particle after being divided into plural portions having different concentrations.

An interface between the core CR and the shell SL may have a concentration gradient in which the concentration of elements existing in the shell SL is lowered as a distance from a center decreases.

The quantum dot QD may have a core-shell structure that includes the core CR including the above-mentioned nanocrystal, and the shell SL surrounding the core CR. The shell SL of the quantum dot QD may serve as a protective layer to reduce or prevent chemical modification of the core CR, and to maintain semiconductor properties, and/or may serve as a charging layer to impart electrophoretic properties to the quantum dot QD. The shell SL may have a single-layer or multi-layer structure. The shell SL of the quantum dot QD may include metal oxides, non-metal oxides, semiconductor compounds, or combinations thereof as an example.

The metal oxides or non-metal oxides may include a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO, or a ternary compound, such as MgAl₂O₄, CoFe₂O₄, NiFe₂O₄, and CoMn₂O₄, although they should not be limited thereto or thereby.

In addition, the semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, although they should not be limited thereto or thereby.

The quantum dot QD may have a full width at half maximum (FWHM) of a light emission wavelength spectrum of about 45 nm or less, about 40 nm or less, or about 30 nm or less. The color purity and the color reproducibility may be improved within this range. In addition, because the light emitted through the quantum dot QD may be emitted in all directions, an optical viewing angle may be improved.

In addition, the quantum dot QD may have a shape commonly used in the art, although it should not be particularly limited. In more detail, spherical, pyramidal, multi-arm, or cubic nanoparticles, nanotubes, nanowires, nanofibers, nanoplatelets, or the like may be applied to the quantum dots.

The quantum dots QD may control the color of the emitted light depending on a particle size thereof, and accordingly, the quantum dots QD may have various emission colors, such as blue, red, and green colors. As a size of the quantum dot QD decreases, the quantum dot QD may emit a light in shorter wavelength region. As an example, in the quantum dot QD having the same core CR, a particle size of the quantum dot emitting the green color light may be smaller than a particle size of the quantum dot emitting the red color light. In addition, in the quantum dot QD having the same core CR, a particle size of the quantum dot QD emitting the blue color light may be smaller than the particle size of the quantum dot QD emitting the green color light, although the present disclosure should not be limited thereto or thereby. According to one or more embodiments, the particle size of the quantum dot may be adjusted according to a material of the shell SL and according to a thickness of the shell SL even in the quantum dot QD having the same core CR.

Meanwhile, when the quantum dots QD have various light-emitting colors, such as the blue color, the red color, and the green color, the cores CR of the quantum dots QD having different light-emitting colors may include different materials from each other.

The quantum dot QD may further include a ligand LG placed outside the shell SL of the quantum dot QD. The ligand LG may be placed on a surface of the shell SL of the quantum dot QD. The ligand LG may increase dispersibility of the quantum dots QD, although this is merely an example. According to one or more embodiments, the quantum dot QD may have a structure in which the ligand LG is not placed on the surface of the quantum dot QD.

FIG. 5 is a cross-sectional view of the display device DD taken along the line I-I′ of FIG. 1.

Referring to FIG. 5, the display device DD may include the first substrate DP, the second substrate PP located above the first substrate DP, and the inner space SP between the first substrate DP and the second substrate PP.

The first substrate DP may include the base layer BS, the circuit element layer DP-CL located on the base layer BS, and the display element layer DP-OL located on the circuit element layer DP-CL.

The base layer BS may provide a base surface on which other components are located. The base layer BS may be a glass substrate, a metal substrate, or a plastic substrate, although it should not be limited thereto or thereby. According to one or more embodiments, the base layer BS may include an inorganic layer, an organic layer, or a composite material layer.

The circuit element layer DP-CL may be located on the base layer BS. In one or more embodiments, the circuit element layer DP-CL may include insulating layers and transistors. The insulating layers may have a stack structure. Each of the transistors may include a control electrode, an input electrode, and an output electrode. As an example, the circuit element layer DP-CL may include a switching transistor and a driving transistor to drive the light-emitting elements ED-B, ED-G, and ED-R of the display element layer DP-OL.

The display element layer DP-OL may be located on the circuit element layer DP-CL. The display element layer DP-OL may include the first, second, and third light-emitting elements ED-B, ED-G, and ED-R and the pixel definition layer PDL.

Each of the first, second, and third light-emitting elements ED-B, ED-G, and ED-R may include the first electrode AE, the hole transport region HTR, the light-emitting layers EL-B, EL-G, and EL-R, the electron transport region ETR, and the second electrode CE.

The first electrode AE may be located on the circuit element layer DP-CL. The first electrode AE may be exposed through the openings OH1, OH2, and OH3 of the pixel definition layer PDL.

The pixel definition layer PDL may be located on the circuit element layer DP-CL and may cover a portion of the first electrode AE. The pixel definition layer PDL may be formed of a polymer resin. As an example, the pixel definition layer PDL may include a polyacrylate-based resin or a polyimide-based resin. In addition, the pixel definition layer PDL may further include an inorganic material in addition to the polymer resin. Meanwhile, the pixel definition layer PDL may include a light-absorbing material, or may include a black pigment or dye. When the pixel definition layer PDL is formed, a carbon black may be used as the black pigment or dye, although the present disclosure should not be limited.

First, second, and third openings OH1, OH2, and OH3 may be defined through the pixel definition layer PDL. The first, second, and third openings OH1, OH2, and OH3 may penetrate the pixel definition layer PDL in a direction from an upper surface to a lower surface of the pixel definition layer PDL. At least a portion of the first electrode AE may be exposed through the first, second, and third openings OH1, OH2, and OH3.

The second electrode CE may be located on the first electrode AE. When the first electrode AE is the anode, the second electrode CE may be the cathode, and when the first electrode AE is the cathode, the second electrode CE may be the anode.

First, second, and third light-emitting layers EL-B, EL-G, and EL-R may be located in the first, second, and third openings OH1, OH2, and OH3, respectively. Each of the first, second, and third light-emitting layers EL-B, EL-G, and EL-R may be located between the first electrode AE and the second electrode CE.

The first light-emitting layer EL-B may include an organic light-emitting material, and each of the second and third light-emitting layers EL-G and EL-R may include a quantum dot as an inorganic light-emitting material. As an example, the first light-emitting layer EL-B may include a blue organic light-emitting material emitting the blue light, the second light-emitting layer EL-G may include a first quantum dot QD-G emitting the green light, and the third light-emitting layer EL-R may include a second quantum dot QD-R emitting the red light.

The organic light-emitting material included in the first light-emitting layer EL-B may include a host material and a dopant material. The organic light-emitting material of the first light-emitting layer EL-B may include a blue light-emitting dopant. When the first light-emitting layer EL-B includes the blue organic light-emitting material with excellent lifespan characteristics compared to a blue quantum dot, the first light-emitting layer EL-B may have excellent luminous efficiency and lifespan characteristics. However, when moisture enters the first light-emitting layer EL-B, the lifespan of the first light-emitting layer EL-B including the organic light-emitting material may be reduced.

The first quantum dot QD-G included in the second light-emitting layer EL-G may be a green light-emitting quantum dot. The second quantum dot QD-R included in the third light-emitting layer EL-R may be a red light-emitting quantum dot. Descriptions on the quantum dot QD with reference to FIG. 4 may be applied to each of the first quantum dot QD-G and the second quantum dot QD-R, and thus, details thereof will not be repeated.

The hole transport region HTR may be located between the first electrode AE and the light-emitting layers EL-B, EL-R, and EL-G, and the electron transport region ETR may be located between the second electrode CE and the light-emitting layers EL-B, EL-R, and EL-G. Descriptions on the hole transport region HTR and the electron transport region ETR with reference to FIG. 3 may be applied to the hole transport region HTR and the electron transport region ETR, and thus, details thereof will not be repeated.

The hole transport region HTR, the light-emitting layer EL-B, EL-R, or EL-G, and the electron transport region ETR of the first, second, and third light-emitting elements ED-B, ED-G, and ED-R may be respectively located in each of the openings OH1, OH2, and OH3, and may be separated from the hole transport region HTR, the light-emitting layer EL-B, EL-R, or EL-G, and the electron transport region ETR of adjacent light-emitting areas. That is, the hole transport region HTR, the light-emitting layers EL-B, EL-R, and EL-G, and the electron transport region ETR may be located in the openings OH1, OH2, and OH3 after being patterned.

The hole transport region HTR, the light-emitting layers EL-B, EL-R, and EL-G, and the electron transport region ETR may be formed by an inkjet printing method, although the present disclosure should not be limited thereto or thereby. According to one or more embodiments, the hole transport region HTR, the light-emitting layers EL-B, EL-R, and EL-G, and the electron transport region ETR may be formed by a method other than the inkjet printing method. In one or more embodiments, at least the portion of the hole transport region HTR or the portion of the electron transport region ETR may extend to, and may be located on, the upper portion of the pixel definition layer PDL, the portion of hole transport region HTR, and/or the portion of the electron transport region ETR located at adjacent light-emitting elements.

The display area DA may include first, second, and third light-emitting areas PXA-B, PXA-G, and PXA-R and the non-light-emitting area NPXA. Descriptions on the light-emitting area PXA with reference to FIG. 1 may be applied to the first, second, and third light-emitting areas PXA-B, PXA-G, and PXA-R, and thus, details thereof will not be repeated.

The first, second, and third light-emitting areas PXA-B, PXA-G, and PXA-R may be defined as areas where the first electrode AE is exposed through the first, second, and third openings OH1, OH2, and OH3, respectively. That is, the first, second, and third light-emitting areas PXA-B, PXA-G, and PXA-R may be distinguished from each other by the pixel definition layer PDL. The first, second, and third light-emitting areas PXA-B, PXA-G, and PXA-R may be areas from which lights generated by the first to third light-emitting elements ED-B, ED-G, and ED-R are emitted, respectively. The first, second, and third light-emitting areas PXA-B, PXA-G, and PXA-R may be spaced apart from each other when viewed in the plane.

The first, second, and third light-emitting areas PXA-B, PXA-G, and PXA-R may be distinguished from each other depending on colors of lights emitted from the light-emitting elements ED-B, ED-G, and ED-R. In the display device DD according to the present disclosure, the first light-emitting area PXA-B may be a blue light-emitting area, the second light-emitting area PXA-G may be a green light-emitting area, and the third light-emitting area PXA-R may be a red light-emitting area.

The light-emitting areas PXA-B, PXA-G, and PXA-R may have different sizes depending on the colors of the lights emitted from the light-emitting layers EL-B, EL-G, and EL-R of the light-emitting element ED-B, ED-G, and ED-R. As an example, in the display device DD, the first light-emitting area PXA-B corresponding to the first light-emitting element ED-B for emitting the blue light may have the largest size, and the second light-emitting area PXA-G corresponding to the second light-emitting element ED-G for emitting the green light may have the smallest size, although the present disclosure should not be limited thereto or thereby. According to one or more embodiments, the light-emitting areas PXA-B, PXA-G, and PXA-R may have size ratios different from those of the light-emitting areas shown in FIG. 5.

The non-light-emitting area NPXA may be defined as an area excluding the first, second, and third light-emitting areas PXA-B, PXA-G, and PXA-R in the display area DA (refer to FIG. 1). The non-light-emitting area NPXA may be defined between the first, second, and third light-emitting areas PXA-B, PXA-G, and PXA-R adjacent to each other, and may correspond to the pixel definition layer PDL. The non-light-emitting area NPXA may define a boundary between the first, second, and third light-emitting areas PXA-B, PXA-G, and PXA-R. The non-light-emitting area NPXA may surround the first, second, and third light-emitting areas PXA-B, PXA-G, and PXA-R.

The second substrate PP may include the base substrate BL and the auxiliary layer FL located on the lower portion of the base substrate BL.

The base substrate BL may provide the base surface on which the auxiliary layer FL is located. The base substrate BL may have a light-transmitting property. Accordingly, the light emitted from the first substrate DP may be viewed by the user after passing through the second substrate PP. As an example, the base substrate BL may be an optically transparent glass substrate, although the present disclosure should not be limited thereto or thereby. According to one or more embodiments, the base substrate BL may be a plastic substrate, a metal substrate, or a composite material substrate.

The auxiliary layer FL may be located on the lower portion of the base substrate BL. The auxiliary layer FL may include a barrier wall BK, the functional layer FS, and a moisture-absorbing layer DH.

The barrier wall BK may include a polymer resin and a liquid-repellent additive. The barrier wall BK may include a light-absorbing material or a pigment or dye. As an example, the barrier wall BK may include a black pigment or a black dye to implement a black barrier wall. The barrier wall BK may include a carbon black, although the present disclosure should not be limited.

First, second, and third barrier wall openings BH1, BH2, and BH3 may be defined through the barrier wall BK to penetrate the barrier wall BK along a direction from an upper surface toward a lower surface of the barrier wall BK. The first, second, and third barrier wall openings BH1, BH2, and BH3 may overlap the first, second, and third openings OH1, OH2, and OH3, respectively. Accordingly, the first, second, and third light-emitting areas PXA-B, PXA-G, and PXA-R may overlap the first, second, and third barrier wall openings BH1, BH2, and BH3, respectively.

The functional layer FS may include the first, second, and third functional layers FS1, FS2, and FS3. The first, second, and third functional layers FS1, FS2, and FS3 may be located in the first, second, and third barrier wall openings BH1, BH2, and BH3, respectively.

The moisture-absorbing layer DH may be located in the first barrier wall opening BH1. The moisture-absorbing layer DH may contact the functional layer FS. The moisture-absorbing layer DH may absorb moisture discharged from the polymer-based material of the functional layer FS.

A sum of a thickness TH1 of the first functional layer and a thickness RH of the moisture-absorbing layer DH may be the same as each of a thickness TH2 of the second functional layer and a thickness TH3 of the third functional layer. Accordingly, the thickness TH1 of the first functional layer may be less than the thickness TH2 of the second functional layer, although the present disclosure should not be limited thereto or thereby.

A first distance DS1 from an upper surface of the first light-emitting layer EL-B included in the first light-emitting element ED-B to a lower surface of the first functional layer FS1 may be substantially the same as a second distance DS2 from an upper surface of the second light-emitting layer EL-G included in the second light-emitting element ED-G to a lower surface of the second functional layer FS2. However, the present disclosure should not be limited thereto or thereby, and the first distance DS1 may be different from the second distance DS2.

The first, second, and third functional layers FS1, FS2, and FS3 may include a polymer-based material. For example, the first, second, and third functional layers FS1, FS2, and FS3 may include an acidic polymer-based material. As an example, the first, second, and third functional layers FS1, FS2, and FS3 may include methacrylic acid, polyacrylic acid, or citric acid.

The polymer-based material included in the first, second, and third functional layers FS1, FS2, and FS3 may emit moisture when exposed to an ultraviolet ray or when affected by thermal conditions. The emitted moisture may reach the first, second, and third light-emitting elements ED-B, ED-G, and ED-R after passing through the inner space SP.

Each of the first, second, and third functional layers FS1, FS2, and FS3 may be closest to one light-emitting element overlapping therewith among the first, second, and third light-emitting elements ED-B, ED-G, and ED-R, and the moisture released from each of the first, second, and third functional layers FS1, FS2, and FS3 may have a “main influence” on one of the light-emitting element closest thereto among the first, second, and third light-emitting elements ED-B, ED-G, and ED-R. In the following descriptions, the expression that the moisture emitted from a specific functional layer has a “main influence” on one light-emitting element means that the moisture emitted from the specific functional layer reaches the one light-emitting element the most among the first, second, and third light-emitting elements ED-B, ED-G, and ED-R.

Due to the moisture that reaches the second light-emitting element ED-G and the third light-emitting element ED-R, the oxygen vacancy may be blocked on the surface of zinc oxide included in the electron transport region ETR of each of the second light-emitting element ED-G and the third light-emitting element ED-R. Accordingly, a positive aging phenomenon in which a trap density is reduced may occur in the second light-emitting element ED-G and in the third light-emitting element ED-R, and the efficiency, such as a material stability and lifespan, of the second light-emitting element ED-G including the first quantum dot QD-G and of the third light-emitting element ED-R including the second quantum dot QD-R, may be improved.

Because the first light-emitting element ED-B includes the organic light-emitting material, the lifespan of the first light-emitting element ED-B may be reduced due to the moisture entering the first light-emitting element ED-B.

However, the display device DD according to the present disclosure includes the moisture-absorbing layer DH located in the first barrier wall opening BH1, and thus, the reduction in lifespan of the first light-emitting element ED-B may be improved.

The moisture-absorbing layer DH may include a moisture-absorbing material. The moisture-absorbing material may include a getter that absorbs and removes the moisture in the gas or liquid form. The moisture-absorbing material may be a known material that absorbs and removes the moisture, and should not be particularly limited as long as the moisture-absorbing material absorbs and removes the moisture.

Because the moisture-absorbing layer DH contacts the first functional layer FS1, the moisture emitted from the polymer-based material included in the first functional layer FS1 may be removed more efficiently than a case where the moisture-absorbing layer DH is separated from the first functional layer FS1. That is, the moisture emitted from the first functional layer FS1, which has the “main influence” on the first light-emitting element ED-B, may be removed, and the reduction in lifespan of the first light-emitting element ED-B may be reduced.

The moisture-absorbing layer DH may have a light-transmitting property. Because the first functional layer FS1 and the base substrate BL also have the light-transmitting property, the lights respectively emitted from the first, second, and third light-emitting elements ED-B, ED-G, and ED-R may be viewed by the user after passing through the first functional layer FS1, the moisture-absorbing layer DH, and the base substrate BL of the second substrate PP.

In the display device DD according to the present embodiment, the lifespan of the second and third light-emitting elements ED-G and ED-R respectively including the quantum dots QD-G and QD-R may be improved by the second and third functional layers FS2 and FS3. In addition, the reduction in lifespan of the first light-emitting element ED-B including the organic light-emitting material OR-B may be reduced or prevented by the moisture-absorbing layer DH.

In addition, a separate process to exclude the first functional layer FS1 only from the first barrier wall opening BH1, which overlaps the first light-emitting element ED-B, among the first, second, and third barrier wall openings BH1, BH2, and BH3 defined through the barrier wall BK, may be omitted. Thus, a manufacturing process of the display device DD may be simplified, and a manufacturing cost of the display device DD may be reduced.

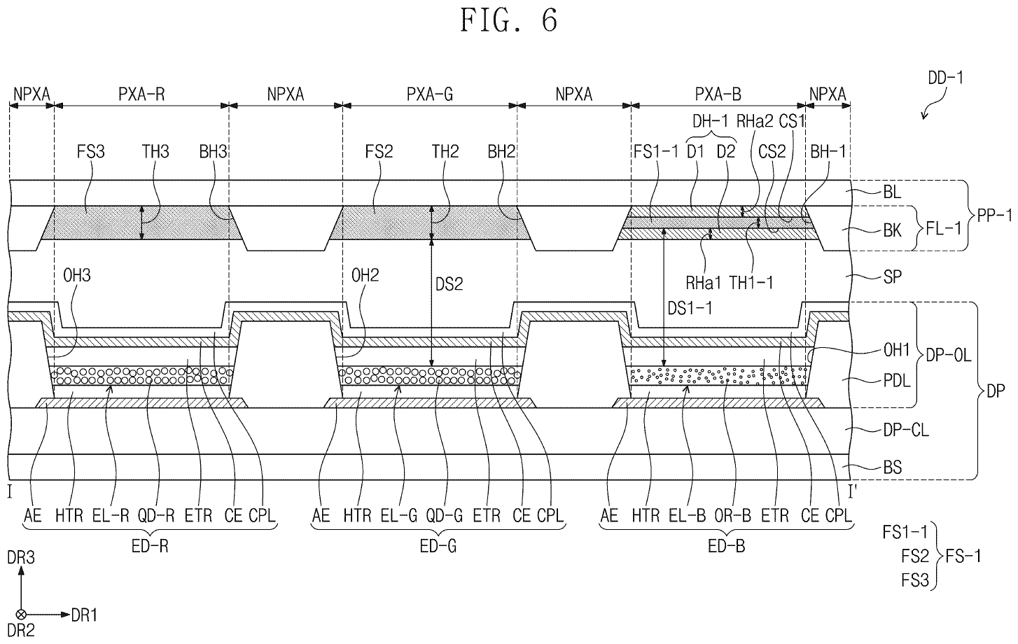

FIG. 6 is a cross-sectional view of a display device DD-1 taken along the line I-I′ of FIG. 1.

Referring to FIG. 6, the display device DD-1 may include a first substrate DP, a second substrate PP-1 located on the first substrate DP, and an inner space SP located between the first substrate DP and the second substrate PP-1. In FIG. 6, the same/similar reference numerals denote the same/similar elements in FIG. 5, and thus, repeated detailed descriptions of the same/similar reference numerals will be omitted.

The first substrate DP may include a base layer BS, a circuit element layer DP-CL located on the base layer BS, and a display element layer DP-OL located on the circuit element layer DP-CL.

The second substrate PP-1 may include a base substrate BL, and an auxiliary layer FL-1 located on a lower portion of the base substrate BL.

The auxiliary layer FL-1 may be located on the lower portion of the base substrate BL. The auxiliary layer FL-1 may include a barrier wall BK, a functional layer FS-1, and a moisture-absorbing layer DH-1.

The functional layer FS-1 may include first, second, and third functional layers FS1-1, FS2, and FS3. The first, second, and third functional layers FS1-1, FS2, and FS3 may be located in first, second, and third barrier wall openings BH1, BH2, and BH3, respectively.

A sum of a thickness TH1-1 of the first functional layer FS1-1 and thicknesses RHa1 and RHa2 of the moisture-absorbing layers DH-1 may be substantially the same as each of a thickness TH2 of the second functional layer and a thickness TH3 of the third functional layer. Accordingly, the thickness TH1-1 of the first functional layer may be less than the thickness TH2 of the second functional layer.

In addition, the first functional layer FS1-1 may have a volume that is less than a volume of the second functional layer FS2. Accordingly, an amount of moisture emitted from the first functional layer FS1-1 may be less than an amount of moisture emitted from the second functional layer FS2.

A first distance DS1-1 from a lower surface of the first functional layer FS1-1 to an upper surface of a first light-emitting layer EL-B may be greater than a second distance DS2 from a lower surface of the second functional layer FS2 to an upper surface of a second light-emitting layer EL-G. Accordingly, a rate at which the moisture emitted from the first functional layer FS1-1 reaches a first light-emitting element ED-B may be less than a rate at which the moisture emitted from the second functional layer FS2 reaches a second light-emitting element ED-G.

Because the display device DD-1 includes the moisture-absorbing layer DH-1 located in the first barrier wall opening BH1, the lifespan of the first light-emitting element ED-B may not be significantly reduced.

The moisture-absorbing layer DH-1 may include a first moisture-absorbing layer D1, and a second moisture-absorbing layer D2 located under the first moisture-absorbing layer D1. A lower surface of the first moisture-absorbing layer D1 may directly contact an upper surface of the first functional layer FS1-1 to form a first contact surface CS1. An upper surface of the second moisture-absorbing layer D2 may directly contact a lower surface of the first functional layer FS1-1 to form a second contact surface CS2. That is, a plurality of contact surfaces CS1 and CS2 may be formed between the functional layer FS1-1 and the moisture-absorbing layer DH-1.

A contact area between the moisture-absorbing layer DH-1 and the first functional layer FS1-1 may be greater when the plural contact surfaces CS1 and CS2 are formed than when a single contact surface CS (refer to FIG. 5) is formed. Accordingly, the moisture-absorbing layer DH-1 may efficiently remove moisture emitted from a polymer-based material of the first functional layer FS1-1.

The second moisture-absorbing layer D2 may be spaced apart from the first moisture-absorbing layer D1 with the first functional layer FS1-1 interposed therebetween.

The first functional layer FS1-1 and the first light-emitting layer EL-B may be spaced from each other with the second moisture-absorbing layer D2 interposed therebetween. That is, when viewed in a direction from the first functional layer FS1-1 to the first light-emitting layer EL-B, the first light-emitting layer EL-B may be blocked by the second moisture-absorbing layer D2. Accordingly, a path through which the moisture emitted from the first functional layer FS1-1 reaches the first light-emitting layer EL-B may be blocked by the second moisture-absorbing layer D2. Therefore, the moisture-absorbing layer DH-1 may efficiently reduce or prevent the moisture emitted from the polymer-based material of the first functional layer FS1-1 reaching the first light-emitting element ED-B.

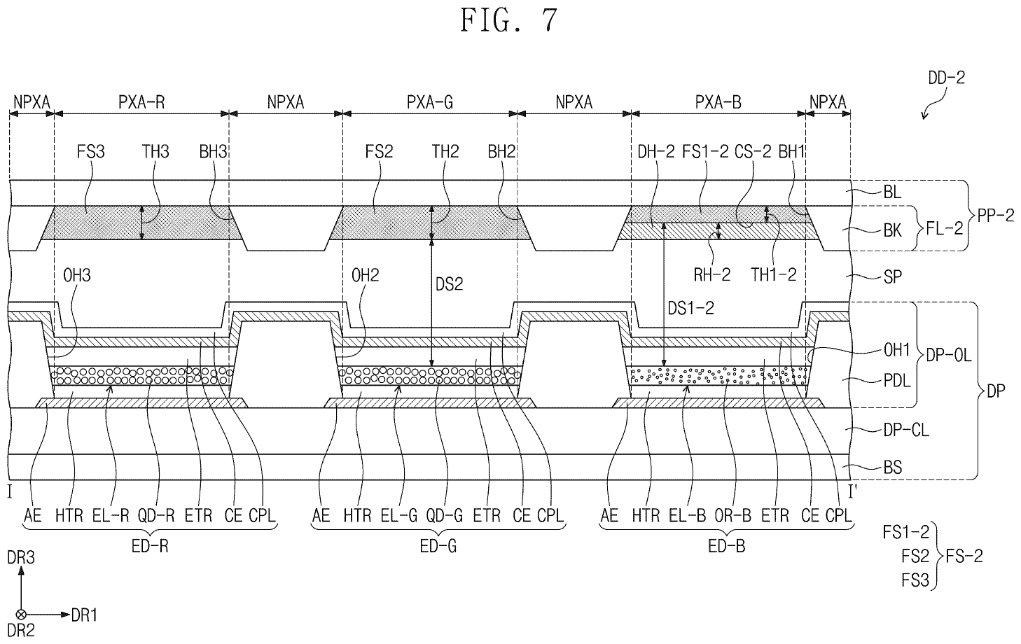

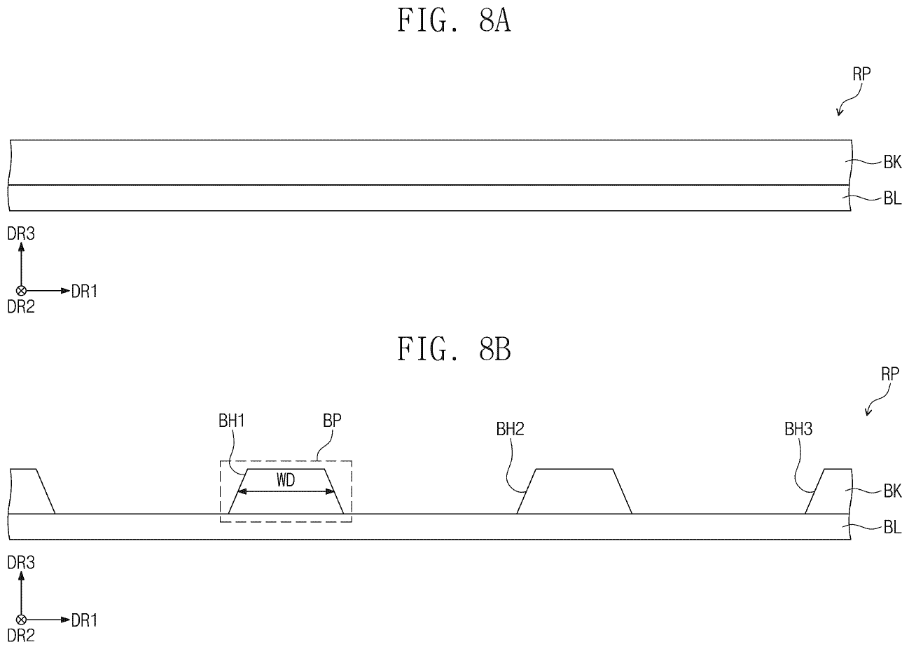

FIG. 7 is a cross-sectional view of a display device DD-2 taken along the line I-I′ of FIG. 1.

Referring to FIG. 7, the display device DD-2 may include a first substrate DP, a second substrate PP-2 located on the first substrate DP, and an inner space SP located between the first substrate DP and the second substrate PP-2. In FIG. 7, the same/similar reference numerals denote the same/similar elements in FIGS. 5 and 6, and thus, repeated detailed descriptions of the same/similar reference numerals will be omitted.

The first substrate DP may include a base layer BS, a circuit element layer DP-CL located on the base layer BS, and a display element layer DP-OL located on the circuit element layer DP-CL.

The second substrate PP-2 may include a base substrate BL, and an auxiliary layer FL-2 located on a lower portion of the base substrate BL.

The auxiliary layer FL-2 may be located on the lower portion of the base substrate BL. The auxiliary layer FL-2 may include a barrier wall BK, a functional layer FS-2, and a moisture-absorbing layer DH-2.

The functional layer FS-2 may include first, second, and third functional layers FS1-2, FS2, and FS3. The first, second, and third functional layers FS1-2, FS2, and FS3 may be located in first, second, and third barrier wall openings BH1, BH2, and BH3, respectively.

A sum of a thickness TH1-2 of the first functional layer FS1-2 and a thickness RH-2 of the moisture-absorbing layer DH-2 may be substantially the same as each of a thickness TH2 of the second functional layer and a thickness TH3 of the third functional layer. The thickness TH1-2 of the first functional layer FS1-2 may be less than the thickness TH2 of the second functional layer FS2, although the present disclosure should not be limited thereto or thereby.

In addition, the first functional layer FS1-2 may have a volume that is less than a volume of the second functional layer FS2. Accordingly, an amount of moisture emitted from the first functional layer FS1-2 may be less than an amount of moisture emitted from the second functional layer FS2.

A first distance DS1-2 from a lower surface of the first functional layer FS1-2 to an upper surface of a first light-emitting layer EL-B may be greater than a second distance DS2 from a lower surface of the second functional layer FS2 to an upper surface of a second light-emitting layer EL-G. Accordingly, a rate at which the moisture emitted from the first functional layer FS1-2 reaches the first light-emitting element ED-B may be less than a rate at which the moisture emitted from the second functional layer FS2 reaches the second light-emitting element ED-G.

Because the display device DD-2 includes the moisture-absorbing layer DH-2 located in the first barrier wall opening BH1, the lifespan of the first light-emitting element ED-B may not be significantly reduced.

The first functional layer FS1-2 may be located on the moisture-absorbing layer DH-2. The first functional layer FS1-2 may directly contact the moisture-absorbing layer DH-2. Referring to FIG. 7, the lower surface of the first functional layer FS1-2 may directly contact the upper surface of the moisture-absorbing layer DH-2 to form a contact surface CS-2.

The first functional layer FS1-2 and the first light-emitting layer EL-B may be spaced apart from each other with the moisture-absorbing layer DH-2 interposed therebetween. That is, when viewed in a direction from the first functional layer FS1-2 to the first light-emitting layer EL-B, the first light-emitting layer EL-B may be blocked by the moisture-absorbing layer DH-2. Accordingly, a path through which the moisture emitted from the first functional layer FS1-2 reaches the first light-emitting layer EL-B may be blocked by the moisture-absorbing layer DH-2. Therefore, the moisture-absorbing layer DH-2 may efficiently reduce or prevent the moisture emitted from a polymer-based material of the first functional layer FS1-2 from reaching the first light-emitting element ED-B.

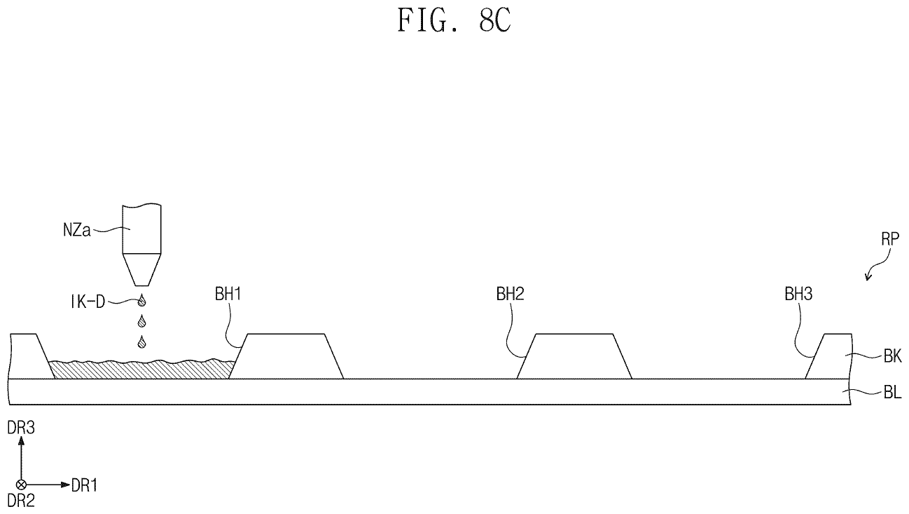

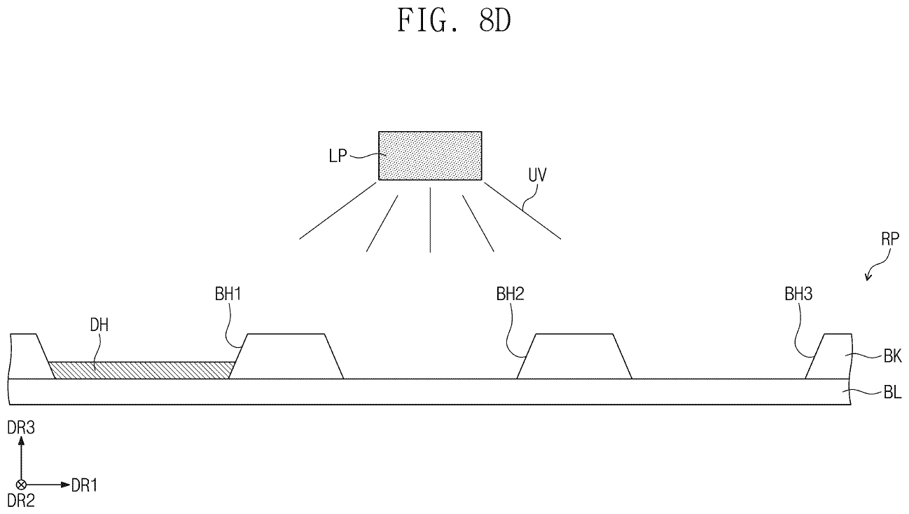

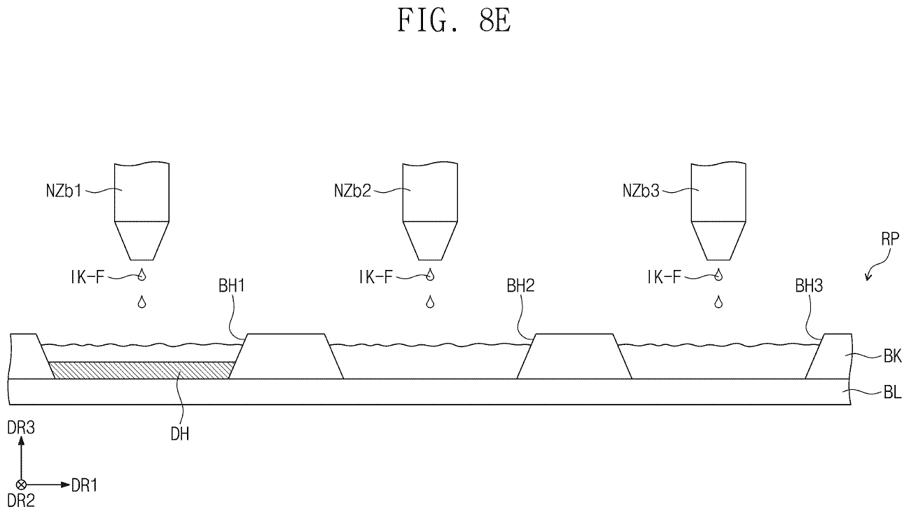

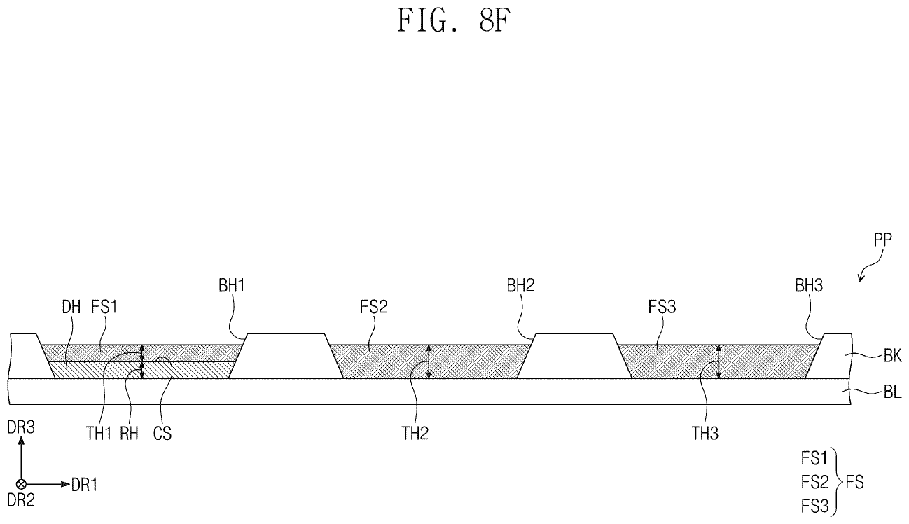

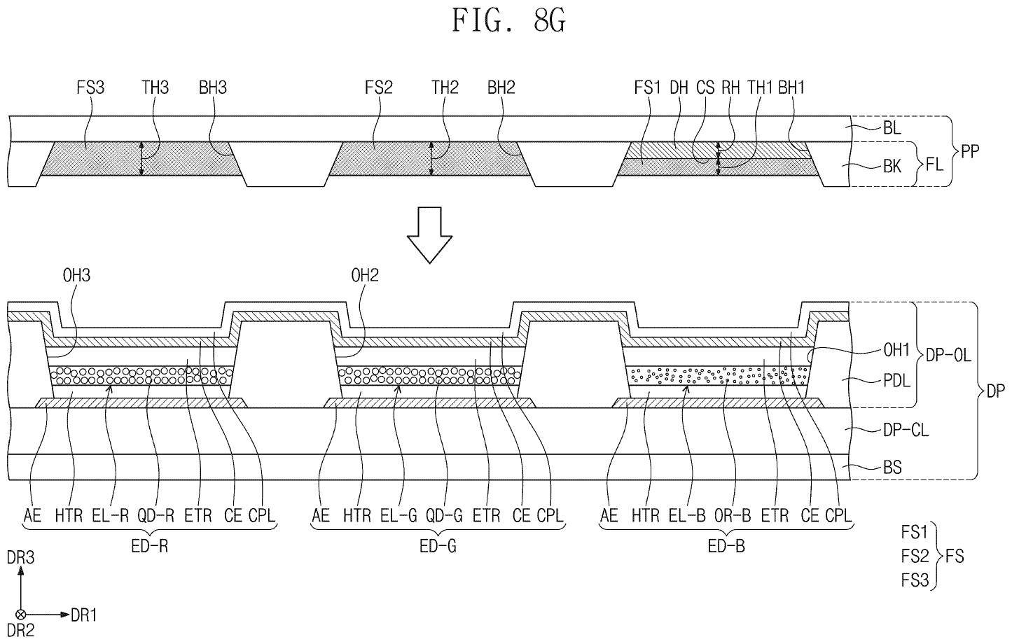

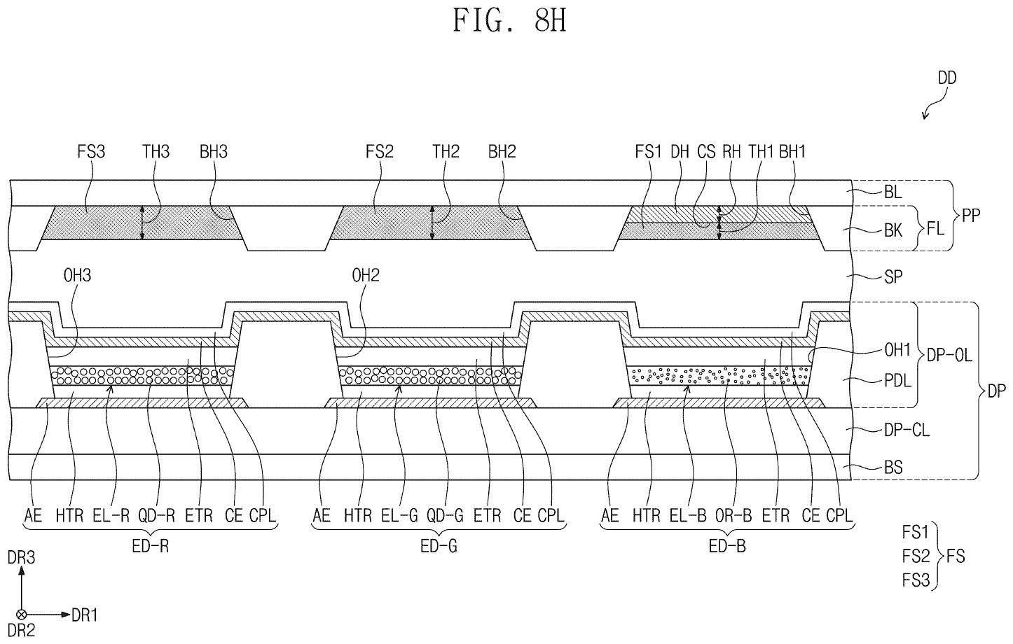

FIGS. 8A to 8H are cross-sectional views illustrating a method of manufacturing the display device according to one or more embodiments of the present disclosure.

The manufacturing method of the display device may include forming the first substrate and the second substrate, and coupling the first and second substrates.

The forming of the second substrate may include providing the base substrate, forming the barrier wall on the base substrate, and etching the barrier wall to form the first to third barrier wall openings.

The forming of the second substrate may include providing the base substrate, forming the barrier wall on the base substrate, etching the barrier wall to form the first to third barrier wall openings, and forming the moisture-absorbing layer including the moisture-absorbing material and the functional layer including the polymer-based material.

In this case, the moisture-absorbing layer may be located in the first barrier wall opening, and the functional layer may be located in the first to third barrier wall openings.

The display device manufactured by the manufacturing method described with reference to FIGS. 8A to 8H may have substantially the same structure as that of a display device described with reference to FIGS. 1 to 5. Accordingly, in FIGS. 8A to 8H, the same reference numerals denote the same elements in FIGS. 1 to 5, and thus, repeated detailed descriptions of the same elements will be omitted.

For the convenience of explanation, FIGS. 8A to 8F show the structure in which the base substrate BL is located at a lowermost position and other components included in the second substrate PP (refer to FIG. 8F) except the base substrate BL are stacked in the third direction DR3. For the convenience of explanation, a second preliminary substrate RP of FIGS. 8A to 8E refers to a structure in which the second substrate PP is not yet completed in the manufacturing process of the second substrate PP (refer to FIG. 8F).

The forming of the second substrate PP (refer to FIG. 5) may include the providing of the base substrate BL and the forming of the barrier wall BK on the base substrate BL. FIG. 8A shows the structure in which the barrier wall BK is located on the base substrate BL.

The barrier wall BK may include the polymer resin and the liquid-repellent additive. The barrier wall BK may include the light-absorbing material or the pigment or dye. As an example, the barrier wall BK may include the black pigment or the black dye to implement the black barrier wall. The barrier wall BK may include a carbon black, although the present disclosure should not be limited.

Referring to FIG. 8B, the barrier wall BK may be etched to form the first, second, and third barrier wall openings BH1, BH2, and BH3.

Each of the first, second, and third barrier wall openings BH1, BH2, and BH3 may penetrate a portion of the barrier wall BK along the direction from the upper surface to the lower surface of the barrier wall BK. The first, second, and third barrier wall openings BH1, BH2, and BH3 may be formed by a photoresist process, although the present disclosure should not be limited thereto or thereby.

For the convenience of explanation, FIG. 8B shows portions BP of the barrier wall that define the barrier wall openings BH1, BH2, and BH3. When viewed in the second direction DR2, a width WD in cross-section of the portions BP of the barrier wall may decrease as it goes to the upper surface of the barrier wall from the lower surface of the barrier wall. That is, the width WD of cross-section of the portions BP of the barrier wall, when viewed in the second direction DR2, may decrease upwardly in the third direction DR3, although this is merely an example. The shape of the barrier wall BK should not be particularly limited as long as the barrier wall openings BH1, BH2, and BH3 are defined to penetrate the portions of the barrier wall BK from the upper surface to the lower surface.

Then, the forming of the moisture-absorbing layer DH including the moisture-absorbing material may be performed.

The process of forming the moisture-absorbing layer DH may include providing the moisture-absorbing material in the liquid form to the first barrier wall opening BH1. FIG. 8C shows a process of dropping the moisture-absorbing material in the liquid form to the first barrier wall opening BH1 using the inkjet printing method.

A first ink IK-D including the moisture-absorbing material in the liquid form may be provided through a first nozzle NZa of an inkjet printing equipment. The first nozzle NZa may be located above the first barrier wall opening BH1 and may spray the first ink IK-D to the first barrier wall opening BH1.

The first ink IK-D may be selectively provided to the first barrier wall opening BH1 by providing the first nozzle NZa of the inkjet printing equipment that provides the first ink IK-D in high resolution. However, the present disclosure should not be limited thereto or thereby, and a portion of the first ink IK-D may be sprayed to the second barrier wall opening BH2 or the third barrier wall opening BH3.

The process of forming the moisture-absorbing layer DH may include irradiating an ultraviolet ray to the moisture-absorbing material in the liquid form to cure the moisture-absorbing material. FIG. 8D shows the irradiating of the ultraviolet ray UV to the moisture-absorbing material in the liquid form to cure the moisture-absorbing material.

An ultraviolet lamp LP may be located above the barrier wall BK. The ultraviolet lamp LP may be spaced apart from the barrier wall BK. FIG. 8D shows a single ultraviolet lamp LP as an example, although the present disclosure should not be limited thereto or thereby, and the ultraviolet lamp LP may be provided in plural.

The moisture-absorbing material in the liquid form may be cured by the ultraviolet ray UV irradiated thereto. As an example, monomers or oligomers contained in the moisture-absorbing material in the liquid form may be polymerized into polymers by a chemical polymerization.

Then, referring to FIGS. 8E and 8F, the process of forming the functional layer FS including the polymer-based material may be performed.

FIG. 8E shows the process of dropping a second ink IK-F in a liquid form to the first to third barrier wall openings BH1, BH2, and BH3 using an inkjet printing method as an example.

First, second, and third nozzles NZb1, NZb2, and NZb3 may provide the second ink IK-F to the first, second, and third barrier wall openings BH1, BH2, and BH3, respectively. The second ink IK-F may include a polymer-based material.

The second ink IK-F may be substantially simultaneously sprayed from the first to third nozzles NZb1, NZb2, and NZb3, although the present disclosure should not be limited thereto or thereby. According to one or more embodiments, at least one of the first to third nozzles NZb1, NZb2, and NZb3 may spray the second ink IK-F at different times.

Referring to FIG. 8E, an amount of the second ink IK-F sprayed from the first nozzle NZb1 may be less than an amount of the second ink IK-F sprayed from the second and third nozzles NZb2 and NZb3.

FIG. 8F shows the functional layer FS formed by curing the second ink IK-F provided to the first to third barrier wall openings BH1, BH2, and BH3.

For the convenience of explanation, the functional layer FS is classified into the first functional layer FS1 formed in the first barrier wall opening BH1, the second functional layer FS2 formed in the second barrier wall opening BH2, and the third functional layer FS3 formed in the third barrier wall opening BH3, although the first, second, and third functional layers FS1, FS2, and FS3 may be a single layer formed by a single process.

Because the amount of the second ink IK-F sprayed from the first nozzle NZb1 is less than the amount of the second ink IK-F sprayed from the second and third nozzles NZb2 and NZb3, the thickness TH1 of the first functional layer may be less than the thickness TH2 of the second functional layer and less than the thickness TH3 of the third functional layer.

Accordingly, the sum of the thickness RH of the moisture-absorbing layer and the thickness TH1 of the first functional layer may be substantially the same as the thickness TH2 of the functional layer formed in the second barrier wall opening BH2 and the thickness TH3 of the functional layer formed in the third barrier wall opening BH3, although the present disclosure should not be limited thereto or thereby.

FIGS. 8E and 8F show the process of forming the functional layer FS using the inkjet printing method as an example, although the present disclosure should not be limited thereto or thereby. As an example, the forming of the functional layer FS may be performed by a photoresist process.

Then, the process of coupling the first substrate DP and the second substrate PP may be performed.

The first substrate DP may include the base layer BS, the pixel definition layer PDL located on the base layer BS and provided with the first to third openings OH1 to OH3 defined therethrough, the first light-emitting layer EL-B located in the first opening OH1 and including the organic light-emitting material OR-B, the second light-emitting layer EL-G located in the second opening OH2 and including the first quantum dot QD-G, and the third light-emitting layer EL-R located in the third opening OH3 and including the second quantum dot QD-R.

Referring to FIG. 8G, the coupling of the first substrate DP and the second substrate PP may include aligning the second substrate PP and the first substrate DP to allow the first to third openings OH1 to OH3 to overlap the first to third barrier wall openings BH1, BH2, and BH3, respectively.

The aligned second substrate PP may move downward to the first substrate DP. However, the present disclosure should not be limited thereto or thereby as long as the second substrate PP and the first substrate DP approach close to each other. As an example, the first substrate DP may move upward to close to the second substrate PP.

The sealing member SL (refer to FIG. 2) may be located between the first substrate DP and the second substrate PP along the edge of each of the first substrate DP and the second substrate PP. The sealing member SL may include an organic material to secure a viscosity to couple the first substrate DP and the second substrate PP, and to secure impact resistance. In addition, the sealing member SL may include an inorganic material, such as frit, an amine-based curing agent, and a photo-initiator.

The sealing member SL may define the inner space SP (refer to FIG. 2) with the first substrate DP and the second substrate PP. The inner space SP may be filled with nitrogen gas.

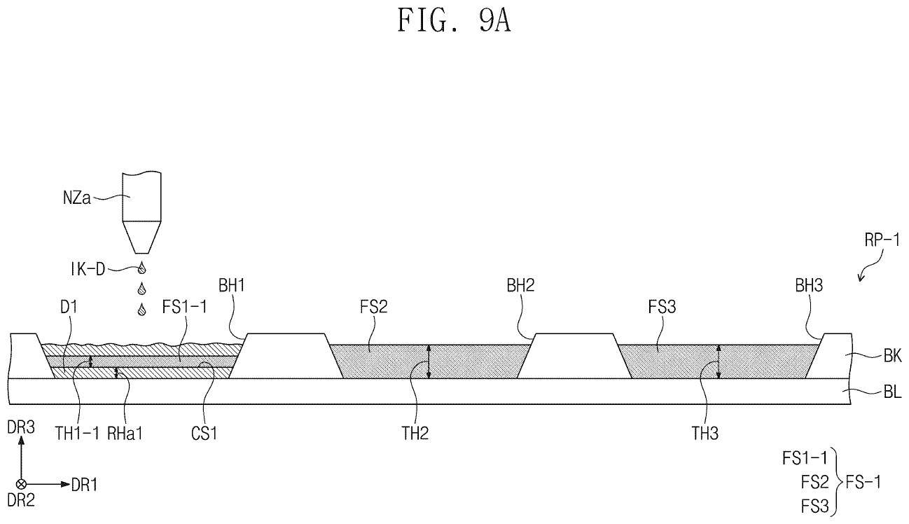

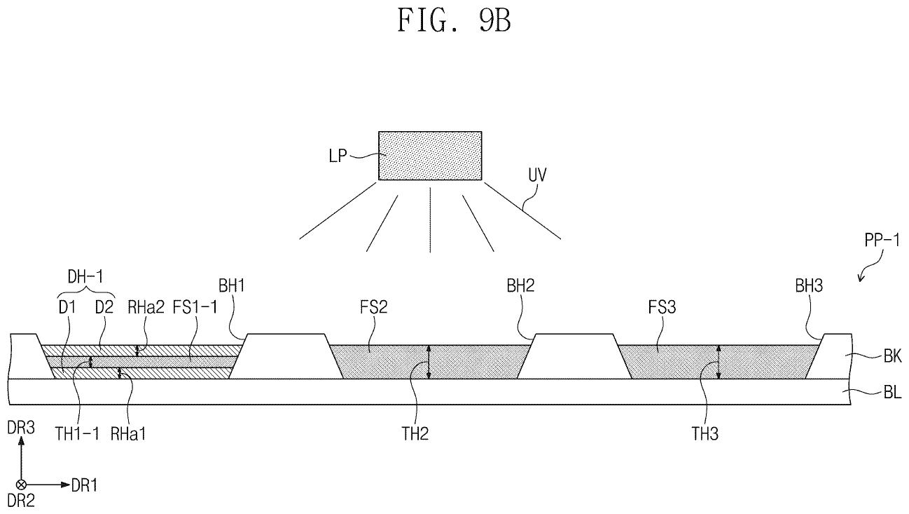

FIGS. 9A and 9B are cross-sectional views illustrating a method of manufacturing the display device according to one or more embodiments of the present disclosure.

The display device manufactured by the manufacturing method described with reference to FIGS. 9A and 9B may have substantially the same structure as that of the display device DD-1 described with reference to FIG. 6. Accordingly, in FIGS. 9A and 9B, the same reference numerals denote the same elements of the display device DD-1 in FIG. 6, and thus, repeated detailed descriptions of the same elements will be omitted.

A preliminary first substrate RP-1 shown in FIG. 9A may be obtained by performing the same/similar processes as those of FIGS. 8A to 8F. Accordingly, the following descriptions with reference to FIGS. 9A and 9B will be focused on different features from those of FIGS. 8A to 8F.

Referring to FIG. 9A, a first ink IK-D may be sprayed to the first barrier wall opening BH1 through a first nozzle NZa. That is, different from the process of forming the preliminary first substrate RP described with reference to FIGS. 8A to 8F, the process of spraying the first ink IK-D to the first barrier wall opening BH1 may be performed multiple times.

In the first barrier wall opening BH1, the functional layer FS1-1 may be located between the first moisture-absorbing layer D1 and the second moisture-absorbing layer D2. That is, a process of forming the functional layer FS1-1 may be performed between a process of forming the first moisture-absorbing layer D1 and a process of forming the second moisture-absorbing layer D2.

The thickness RHa1 of the first moisture-absorbing layer and the thickness TH1-1 of the first functional layer, which are included in the preliminary first substrate RP-1 shown in FIG. 9A, may be different from the thickness RH of the moisture-absorbing layer and the thickness TH1 of the first functional layer described with reference to FIG. 8F.

Referring to FIG. 9B, an ultraviolet ray UV may be irradiated to a moisture-absorbing material in a liquid form to cure the moisture-absorbing material.

An ultraviolet lamp LP may be located above the barrier wall BK. The ultraviolet lamp LP may be spaced apart from the barrier wall BK. The first ink IK-D provided on the first functional layer FS1-1 may be cured by the ultraviolet ray UV, and may be formed as the second moisture-absorbing layer D2. As an example, monomers or oligomers contained in the moisture-absorbing material in the liquid form may be polymerized into polymers by a chemical polymerization.

Then, processes that are the same/similar as those described with reference to FIGS. 8G and 8H may be performed on the preliminary first substrate RP-1 shown in FIG. 9B, and the display device DD-1 described with reference to FIG. 6 may be manufactured.

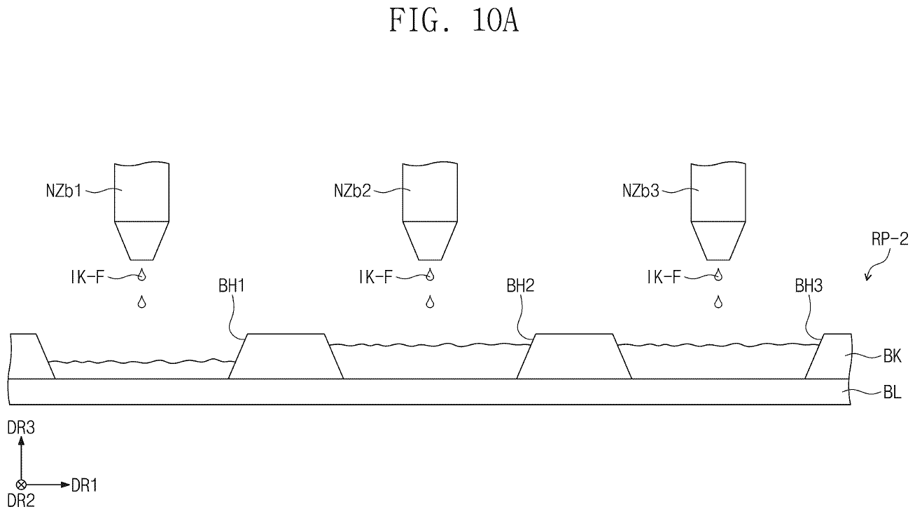

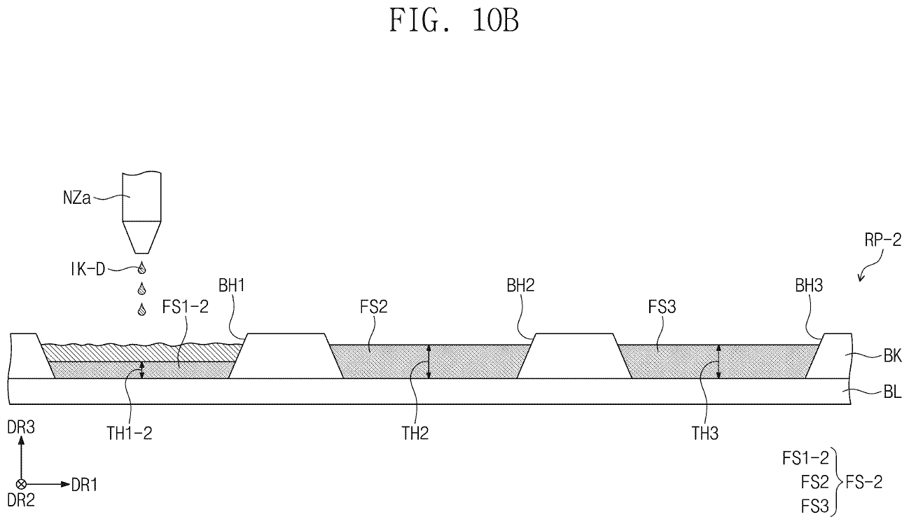

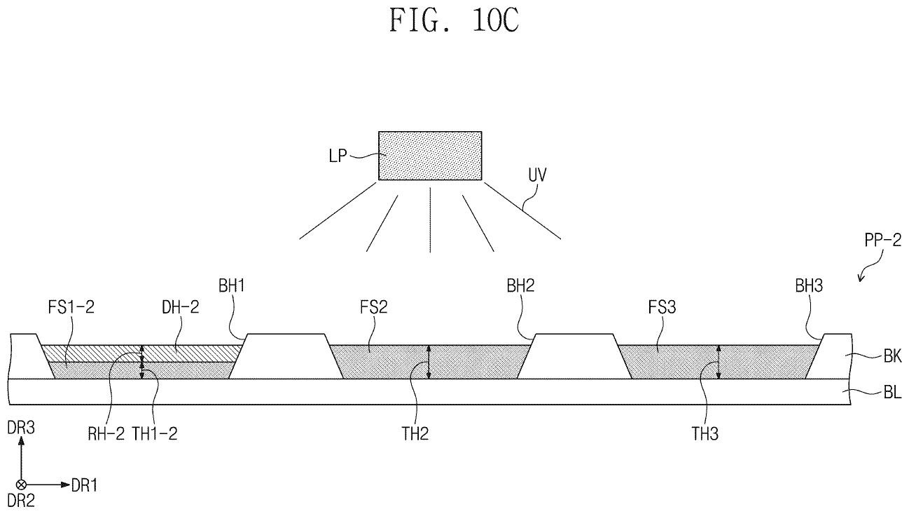

FIGS. 10A to 10C are cross-sectional views illustrating a method of manufacturing the display device according to one or more embodiments of the present disclosure.

The display device manufactured by the manufacturing method described with reference to FIGS. 10A to 10C may have substantially the same structure as that of the display device DD-2 described with reference to FIG. 7. Accordingly, in FIGS. 10A to 10C, the same reference numerals denote the same elements of the display device DD-2 in FIG. 7, and thus, repeated detailed descriptions of the same elements will be omitted.

A preliminary first substrate RP-2 shown in FIG. 10A may be obtained by performing the same/similar processes as those of FIGS. 8A and 8B. Accordingly, the following descriptions with reference to FIGS. 10A to 10C will be focused on different features from those of FIGS. 8A to 8F.

Referring to FIG. 10A, a process of forming a functional layer FS-2 may be performed on the preliminary first substrate RP-2. That is, different from the process of forming the preliminary first substrate RP described with reference to FIGS. 8A to 8H, the process of forming the functional layer FS-2 may be performed prior to a process of forming a moisture-absorbing layer DH-2.

A second ink IK-F may be sprayed to a first barrier wall opening BH1 through a first nozzle NZb1. The second ink IK-F may be directly sprayed onto a base substrate BL exposed through the first barrier wall opening BH1.

Referring to FIG. 10B, a first ink IK-D may be provided to the first barrier wall opening BH1. That is, when the second ink IK-F (refer to FIG. 10A) is cured and a first functional layer FS1-2 is formed, the first ink IK-D may be provided onto the first functional layer FS1-2. The first ink IK-D may be sprayed onto the first functional layer FS1-2 through a first nozzle NZa.

Referring to FIG. 10C, an ultraviolet ray UV may be irradiated to a moisture-absorbing material to cure the moisture-absorbing material. An ultraviolet lamp LP may be located above a barrier wall BK. The ultraviolet lamp LP may be spaced apart from the barrier wall BK. The first ink IK-D provided on the first functional layer FS1-2 may be cured by the ultraviolet ray UV, and may be formed as a moisture-absorbing layer DH-2. As an example, monomers or oligomers contained in the moisture-absorbing material in the liquid form may be polymerized into polymers by a chemical polymerization.

Then, processes that are the same/similar as those described with reference to FIGS. 8G and 8H may be performed on the preliminary first substrate RP-2 shown in FIG. 10C, and the display device DD-2 described with reference to FIG. 7 may be manufactured.

Although the embodiments of the present disclosure have been described, it is understood that the present disclosure should not be limited to these embodiments, and that various changes and modifications can be made by one ordinary skilled in the art within the spirit and scope of the present disclosure as hereinafter claimed. Therefore, the disclosed subject matter should not be limited to any single embodiment described herein, and the scope of the present present disclosure shall be determined according to the attached claims, with functional equivalents thereof to be included therein.

What is claimed is:

1. A display device comprising:
a first substrate comprising:
a base layer;
a pixel definition layer above the base layer, and defining a first opening and a second opening;
a first light-emitting layer in the first opening, and comprising an organic light-emitting material; and
a second light-emitting layer in the second opening, and comprising a first quantum dot; and
a second substrate above the first substrate, and comprising:
a base substrate;
a barrier wall under the base substrate, and defining a first barrier wall opening overlapping the first opening, and a second barrier wall opening overlapping the second opening;
a first functional layer in the first barrier wall opening, and comprising a polymer-based material;
a moisture-absorbing layer in the first barrier wall opening for absorbing a moisture emitted from the polymer-based material; and
a second functional layer in the second barrier wall opening, and comprising the polymer-based material.

2. The display device of claim 1, wherein the polymer-based material of the first functional layer comprises methacrylic acid, polyacrylic acid, or citric acid.

3. The display device of claim 1, wherein the moisture-absorbing layer is above, and directly contacts, the first functional layer.

4. The display device of claim 1, wherein the first functional layer has a thickness that is less than a thickness of the second functional layer.

5. The display device of claim 1, wherein a sum of a thickness of the first functional layer and a thickness of the moisture-absorbing layer is substantially equal to a thickness of the second functional layer.

6. The display device of claim 1, wherein an upper surface of the moisture-absorbing layer contacts a lower surface of the base substrate.

7. The display device of claim 1, wherein the moisture-absorbing layer comprises a first moisture-absorbing layer, and a second moisture-absorbing layer under the first moisture-absorbing layer with the first functional layer therebetween.

8. The display device of claim 7, wherein a lower surface of the first moisture-absorbing layer directly contacts an upper surface of the first functional layer, and
wherein an upper surface of the second moisture-absorbing layer directly contacts a lower surface of the first functional layer.

9. The display device of claim 1, wherein the first functional layer is above, and directly contacts, the moisture-absorbing layer.

10. The display device of claim 1, wherein a distance from a lower surface of the first functional layer to an upper surface of the first light-emitting layer is greater than a distance from a lower surface of the second functional layer to an upper surface of the second light-emitting layer, and
wherein the first functional layer is blocked by the moisture-absorbing layer when viewed in a direction from the first light-emitting layer to the first functional layer.

11. The display device of claim 1, further comprising a sealing member along an edge of the first substrate and the second substrate, and defining an inner space with the first substrate and the second substrate.

12. The display device of claim 1, wherein the base substrate comprises a glass material, and
wherein the first functional layer, the moisture-absorbing layer, and the base substrate have a light-transmitting property.

13. The display device of claim 1, wherein the pixel definition layer defines a third opening,
wherein the first substrate further comprises a third light-emitting layer comprising a second quantum dot in the third opening,
wherein the barrier wall defines a third barrier wall opening overlapping the third opening, and
wherein the second substrate further comprises a third functional layer in the third barrier wall opening, and comprising a polymer-based material.

14. The display device of claim 13, wherein the organic light-emitting material emits a blue light, wherein the first quantum dot emits a green light, and wherein the second quantum dot emits a red light.

15. A method of manufacturing a display device, the method comprising:
forming a second substrate by:
providing a base substrate;
forming a barrier wall on the base substrate;
etching the barrier wall to form a first barrier wall opening, a second barrier wall opening, and a third barrier wall opening; and
forming a moisture-absorbing layer comprising a moisture-absorbing material in the first barrier wall opening;
forming a functional layer comprising a polymer-based material, in the first barrier wall opening, the second barrier wall opening, and the third barrier wall opening;
forming a first substrate; and
coupling the first substrate and the second substrate.

16. The method of claim 15, wherein the forming of the moisture-absorbing layer comprises:
providing a moisture-absorbing material in a liquid form to the first barrier wall opening; and
curing the moisture-absorbing material by irradiating an ultraviolet ray.

17. The method of claim 15, wherein the forming of the moisture-absorbing layer comprises:
providing a moisture-absorbing material in a liquid form to the first barrier wall opening;
forming a first moisture-absorbing layer by irradiating an ultraviolet ray; and
providing the moisture-absorbing material in the liquid form on the first moisture-absorbing layer; and
forming a second moisture-absorbing layer by irradiating an ultraviolet ray.

18. The method of claim 17, wherein the forming of the functional layer is performed between the forming of the first moisture-absorbing layer and the forming of the second moisture-absorbing layer.

19. The method of claim 15, wherein the forming of the functional layer is performed by an inkjet process or a photoresist process.

20. The method of claim 15, wherein the first substrate comprises a base layer, a pixel definition layer above the base layer and defining a first opening, a second opening, and a third opening, a first light-emitting layer in the first opening and comprising an organic light-emitting material, a second light-emitting layer in the second opening and comprising a first quantum dot, and a third light-emitting layer in the third opening and comprising a second quantum dot, and
wherein the coupling of the first and second substrates comprises aligning the first opening, the second opening, and the third opening to respectively overlap the first barrier wall opening, the second barrier wall opening, and the third barrier wall opening.
